(19) United States
(12) Patent Application Publication
(10) Pub. No.: US 2026/0146180 A1
(43) Pub. Date: May 28, 2026

(54) CERIA BASED COMPOSITIONS AND METHODS FOR HARD CARBON POLISHING

(71) Applicant: ENTEGRIS, INC., Billerica, MA (US)

(72) Inventors: Alex Villani-Gale, Chicago, IL (US); Brian Reiss, Woodridge, IL (US); Yuqing Yang, Naperville, IL (US); Sudeep Pallikkara Kuttiatoor, Naperville, IL (US); Elliot Knapton, Aurora, IL (US)

(21) Appl. No.: 19/397,928

(22) Filed: Nov. 22, 2025

Related U.S. Application Data
(60) Provisional application No. 63/724,282, filed on Nov. 23, 2024.

(51) Int. Cl. C09G 1/02; B24B 37/04; C09K 3/14

(52) U.S. Cl. CPC C09G 1/02; B24B 37/044; C09K 3/1409; H10P 52/407

(57) ABSTRACT

A chemical mechanical polishing composition comprises, consists of, or consists essentially of a liquid carrier, ceria particles in the liquid carrier, an oxidizer including an iron (iii) compound or a cerium (IV) compound, an acid having a ligand including an aromatic group or a nitrogen containing aromatic group, and has a pH of less than about 4. A method for polishing a hard carbon containing substrate includes contacting the substrate with the polishing composition and abrading the substrate with the polishing composition to remove a portion of the hard carbon layer from the substrate and thereby polish the substrate.

### BACKGROUND OF THE INVENTION

Chemical mechanical polishing (CMP) compositions and methods for polishing (or planarizing) the surface of a substrate are well known. Polishing compositions (also known as polishing slurries, CMP slurries, and CMP compositions) for dielectric layers (such as silicon oxide) on a semiconductor substrate may include abrasive particles suspended in an aqueous solution and various chemical additives such as polishing rate accelerators, topography control agents, buffers, and the like.

In a conventional CMP operation, the substrate (wafer) to be polished is mounted on a carrier which is in turn mounted on a carrier assembly and positioned in contact with a polishing pad in a CMP polishing tool. The carrier assembly provides a controlled pressure to the substrate against the polishing pad. The substrate and pad are moved relative to one another by an external driving force. The relative motion of the substrate and pad abrades and removes a portion of the material from the surface of the substrate, thereby polishing the substrate. The polishing of the substrate by the relative movement of the pad and the substrate may be further aided by the chemical activity of the polishing composition and/or the mechanical activity of an abrasive suspended in the polishing composition.

Hard amorphous carbon layers are finding increased usage in semiconductor devices, particularly in DRAM and 3D NAND devices. While using these hard carbon layers can provide certain advantages, achieving suitably high polishing rates and throughput using conventional CMP compositions and methods is proving to be difficult. There is a need in the industry for improved CMP compositions and methods capable of polishing hard carbon layers with high removal rates.

### BRIEF SUMMARY OF THE INVENTION

A chemical mechanical polishing composition is disclosed. The composition comprises, consists of, or consists essentially of a liquid carrier, ceria particles in the liquid carrier; an oxidizer including an iron (iii) compound or a cerium (IV) compound, an acid having a ligand including an aromatic group or a nitrogen containing aromatic group, and a pH of less than about 4. The composition may be particularly well suited for polishing a substrate having a hard carbon layer.

### DETAILED DESCRIPTION OF THE INVENTION

Chemical mechanical polishing compositions and methods for using those compositions to polish a substrate including a hard carbon layer are disclosed. In one example embodiment, a composition includes ceria particles in a liquid carrier, an oxidizer including an iron (iii) compound or a cerium (IV) compound, an acid having a ligand including an aromatic group or a nitrogen containing aromatic group, and a pH of less than about 4.

One example method for polishing a hard carbon containing substrate includes contacting the substrate with the polishing composition disclosed in the preceding paragraph and abrading the substrate with the polishing composition to remove a portion of the hard carbon layer from the substrate and thereby polish the substrate. In example embodiments, the hard carbon layer has an elastic modulus of greater than about 7 GPa and/or a stiffness of greater than about 150 N/m (e.g., about 200 N/m).

The disclosed polishing composition includes ceria particles in (e.g., dispersed or otherwise disposed in) a liquid carrier. The disclosed polishing compositions may contain substantially any suitable ceria particles, for example, including wet process ceria, precipitated ceria, fumed ceria, sintered (calcined) ceria, and/or condensation polymerized ceria particles. By ceria particles it is meant particles that are primarily or mostly ceria. Suitable ceria particles may also include doped ceria particles or ceria particles including small amounts (such as a few percent) of other elements or compounds, such as other oxides. Ceria particles suitable for polishing substrates are well known in the CMP industry and are commercially available.

The ceria particles in the disclosed compositions may have substantially any particle size suitable for CMP operations. It will be appreciated that the measured particle size of a particle (such as a ceria particle), for example, suspended in a liquid carrier, commonly depends on the measurement technique. As such, when the ceria particles are measured using dynamic light scattering, such as with a Malvern Zetasizer®, the discrete ceria particles may have an average particle size (such as a weight average particle size or a number average particle size) greater than about 1 nm (e.g., greater than about 10 nm). Moreover, the ceria particles may be characterized as having an average particle size less than about 1 μm (e.g., less than about 500 nm). Accordingly, the ceria particles may be characterized as having an average particle size in a range from about 1 nm to about 1 μm (e.g., from about 10 nm to about 500 nm).

In preferred embodiments, the ceria particles may have an average particle size of about 20 nm or more (e.g., about 40 nm or more, about 60 nm or more, about 80 nm or more, or about 100 nm or more). Alternatively, in preferred embodiments, the ceria particles may have an average particle size of about 400 nm or less (e.g., about 300 nm or less, about 250 nm or less, about 200 nm or less, or about 150 nm or less). Accordingly, in such preferred embodiments, the ceria particles may have an average particle size within a range bounded by any two of the aforementioned endpoints. For example, the first ceria particles may have an average particle size of about 20 nm to about 400 nm (e.g., about 40 nm to about 300 nm, about 60 nm to about 250 nm, or about 100 nm to about 200 nm). In such embodiments, the ceria particle size may be as measured using a CPS Disc Centrifuge Particle size analyzer.

The ceria particles may optionally also (or alternatively) be characterized as having a Brunauer-Emmett-Teller (BET) surface area of greater than about 5 m²/g (e.g., greater than about 10 m²/g or greater than about 15 m²/g). The BET surface area may further be less than about 200 m²/g (e.g., less than about 180 m²/g, less than about 150 m²/g, less than about 120 m²/g, or less than about 100 m²/g). Accordingly, the ceria particles may have a BET surface area in a range bounded by any two of the aforementioned endpoints, for example, from about 5 m²/g to about 200 m²/g (e.g., from about 10 m²/g to about 150 m²/g, or from about 15 m²/g to about 100 m²/g).

The ceria particles may be present in the polishing composition at any suitable concentration. A desired concentration of ceria particles may depend, for example, on the type of hard carbon being polished, the desired removal rate of hard carbon, and desired removal rate selectivities to other films such as other oxides or nitrides, the size of the substrate (e.g., wafers) being polished, the type of polishing tool being utilized, and cost constraints. In example embodiments, the ceria particles may be present in the polishing composition at a concentration of about 0.01 wt. % or more at point of use (e.g., about 0.03 wt. % or more, about 0.05 wt. % or more, about 0.08 wt. % or more, or about 0.1 wt. % or more). Alternatively, or in addition, the ceria particles may be present in the polishing composition at a concentration of about 5 wt. % or less at point of use (e.g., about 2 wt. % or less, about 1 wt. % or less, about 0.8 wt. % or less, or about 0.5 wt. % or less). Accordingly, the ceria particles may be present in the polishing composition at a concentration within a range bounded by any two of the aforementioned endpoints. For example, the ceria particles may be present in the polishing composition at point of use at a concentration range from about 0.01 wt. % to about 5 wt. % (e.g., about 0.05 wt. % to about 1 wt. % or from about 0.1 wt. % to about 0.5 wt. %).

The polishing composition further includes an oxidizer including an iron (III) or cerium (IV) containing compound. For example, an oxidizer including an iron (III) containing compound may include a ferric (iron III) compounds such as ferric nitrate, ferric sulfate, ferric halides, including fluorides, chlorides, bromides, and iodides, as well as perchlorates, perbromates and periodates, and organic iron compounds such as ferric acetates, carboxylic acids, acetylacetonates, citrates, gluconates, malonates, oxalates, phthalates, and succinates, and mixtures thereof such that the composition includes ferric containing ions. In most preferred embodiments, the iron (III) containing compound includes a ferric nitrate compound such as ferric nitrate nonahydrate.

Likewise, an oxidizer including a cerium (IV) containing compound may include ceric (cerium IV) compounds such as ceric nitrate, ceric sulfate, ceric halides, including fluorides, chlorides, bromides, and iodides, as well as perchlorates, perbromates and periodates, and organic ceric compounds such as ceric acetates, carboxylic acids, acetylacetonates, citrates, gluconates, malonates, oxalates, phthalates, and succinates, and mixtures thereof. In most preferred embodiments, the cerium (IV) containing compound includes cerium ammonium nitrate (CAN).

In example embodiments, the composition does not include a peroxy-type oxidizer. A peroxy-type oxidizer is any oxidizer with at least one peroxy (—O—O—) group. For example, a peroxy-type oxidizer is an organic peroxide, inorganic peroxide, or combination thereof. Examples of compounds containing at least one peroxy group include, but are not limited to, hydrogen peroxide and its adducts such as urea hydrogen peroxide and percarbonates (e.g., sodium percarbonate), organic peroxides such as benzoyl peroxide, peracetic acid, perboric acid, and di-tert-butyl peroxide, monopersulfates (SO₅²⁻), dipersulfates (S₂O₈²⁻), and sodium peroxide.

The oxidizer may be present in the polishing composition at any suitable concentration. The desired concentration may depend, for example, on the type of hard carbon being polished, the desired removal rate of hard carbon, and desired removal rate selectivities to other films such as other oxides or nitrides, the size of the substrate (e.g., wafers) being polished, the type of polishing tool being utilized, and cost constraints. In example embodiments, the oxidizer may be present in the polishing composition at a concentration of about 0.5 mM or more at point of use (e.g., about 1 mM or more, about 2 mM or more, or about 3 mM or more). Alternatively, or in addition, the oxidizer may be present in the polishing composition at a concentration of about 50 mM or less at point of use (e.g., about 25 mM or less, about 20 mM or less, or about 15 mM or less). Accordingly, the oxidizer may be present in the polishing composition at a concentration within a range bounded by any two of the aforementioned endpoints. For example, the oxidizer may be present in the polishing composition at point of use at a concentration range from about 0.5 mM to about 50 mM (e.g., from about 1 mM to about 25 mM, from about 2 mM to about 20 mM, or from about 3 mM to about 15 mM).

The polishing composition further includes a hard carbon polishing rate enhancing ligand. In preferred embodiments, the rate enhancing ligand may include an acid having an aromatic group or a nitrogen containing aromatic group. Preferred rate enhancing ligands may include, for example, picolinic acid, pyrrole carboxylic acid, 6-hydroxypicolinic acid, 4-aminobenzoic acid, and benzohydroxamic acid. Picolinic acid, pyrrole carboxylic acid, and 4-aminobenzoic acid may be most preferred in certain compositions.

The polishing composition may include substantially any suitable amount of the rate enhancing ligand. In general, the concentration is desirably high enough to provide sufficient rate enhancement, but low enough to not cause other undesirable polishing effects such as colloidal instability. In example embodiments, the concentration of the rate enhancing ligand in the polishing composition may be about 1 mM or more at point of use (e.g., about 2 mM or more, about 3 mM or more, or about 5 mM or more). Alternatively, or in addition, the concentration of the rate enhancing ligand may be about 100 mM or less at point of use (e.g., about 50 mM or less, about 40 mM or less, or about 30 mM or less, or about 20 mM or less). Accordingly, the concentration of the rate enhancing ligand may be within a range bounded by any two of the aforementioned endpoints. For example, the concentration of the rate enhancing ligand at point of use in the composition may be from about 1 mM to about 100 mM (e.g., from about 2 mM to about 50 mM, from about 3 mM to about 30 mM, or from about 5 mM to about 20 mM).

A liquid carrier is generally used to facilitate the application of the ceria particles, the oxidizer, and the rate enhancing ligand to the surface of the substrate to be polished. The liquid carrier may include any suitable carrier (e.g., a solvent) including lower alcohols (e.g., methanol, ethanol, etc.), ethers (e.g., dioxane, tetrahydrofuran, etc.), water, and mixtures thereof. Preferably, the liquid carrier comprises, consists essentially of, or consists of water, more preferably deionized water.

The polishing composition is generally acidic having a pH of less than about 5 (e.g., less than about 4.5. less than about 4, or less than about 3.5). The polishing composition may have a pH of greater than about 1 (e.g., greater than about 2, greater than about 2.5, or greater than about 3). Accordingly, the polishing composition may have a pH in a range bounded by any two of the aforementioned endpoints, for example, in a range from about 1 to about 5 (e.g., from about 2 to about 4.5, from about 2 to about 4, or from about 2.5 to about 3.5).

The pH of the polishing composition may be achieved and/or maintained by any suitable means. The polishing composition may include substantially any suitable pH adjusting agents or buffering systems. For example, suitable pH adjusting agents may include acetic acid, nitric acid, ammonium hydroxide, potassium hydroxide, triethanolamine, and the like while suitable buffering agents may include phosphates, sulfates, acetates, malonates, oxalates, borates, ammonium salts, and the like.

Example embodiments of the disclosed polishing compositions have been observed to achieve higher hard carbon polishing rates when the electrical conductivity of the polishing composition is suitably high. Example polishing compositions may therefore advantageously have an electrical conductivity of greater than about 2000 μS/cm (e.g., greater than about 2200 μS/cm, greater than about 2400 μS/cm, greater than about 2600 μS/cm, greater than about 2800 μS/cm, or greater than about 3000 μS/cm). The electrical conductivity of the polishing composition may also be less than about 10,000 μS/cm (e.g., less than about 8000 μS/cm, less than about 7000 μS/cm, less than about 6000 μS/cm, less than about 5500 μS/cm, or less than about 5000 μS/cm). Accordingly, the polishing composition may have an electrical conductivity within a range bounded by any two of the aforementioned endpoints. For example, the polishing composition may have an electrical conductivity in a range from about 2000 μS/cm to about 10,000 μS/cm (e.g., from about 2000 μS/cm to about 8000 μS/cm, from about 2200 μS/cm to about 7000 μS/cm, from about 2400 μS/cm to about 6000 μS/cm, from about 2600 μS/cm to about 5500 μS/cm, or from about 2800 μS/cm to about 5000 μS/cm). It will be appreciated that the conductivity value of the composition may be selected (or tuned) by increasing the ionic strength of the composition, for example, adding small amounts of an ionic compound such as potassium nitrate.

The polishing composition may optionally further include a biocide. The biocide may include any suitable biocide, for example an isothiazolinone biocide. The amount of biocide in the polishing composition typically is in a range from about 1 ppm to about 50 ppm by weight at point of use or in a concentrate, and preferably from about 1 ppm to about 20 ppm.

The disclosed polishing compositions may further optionally include substantially any other suitable chemical mechanical polishing additives, for example, such as a cationic polymer and/or surfactant intended to inhibit silicon oxide removal rates and thereby improve the hard carbon to silicon oxide selectivity and/or an anionic polymer and/or surfactant to inhibit silicon nitride removal rates and thereby improve the hard carbon to silicon nitride selectivity. Example cationic polymers include but are not limited to poly(vinylimidazolium), poly(methacryloyloxyethyltrimethylammonium) chloride (polyMADQUAT), poly(diallyldimethylammonium) chloride (polyDADMAC) (i.e., Polyquaternium-6), poly(dimethylamine-co-epichlorohydrin), poly[bis(2-chloroethyl) ether-alt-1,3-bis[3-(dimethylamino) propyl]urea] (i.e., Polyquaternium-2), copolymers of hydroxyethyl cellulose and diallyldimethylammonium (i.e., Polyquaternium-4), copolymers of acrylamide and diallyldimethylammonium (i.e., Polyquaternium-7), quaternized hydroxyethylcellulose ethoxylate (i.e., Polyquaternium-10), copolymers of vinylpyrrolidone and quaternized dimethylaminoethyl methacrylate (i.e., Polyquaternium-11), copolymers of vinylpyrrolidone and quaternized vinylimidazole (i.e., Polyquaternium-16), Polyquaternium-24, a terpolymer of vinylcaprolactam, vinylpyrrolidone, and quaternized vinylimidazole (i.e., Polyquaternium-46), 3-Methyl-1-vinylimidazolium methyl sulfate-N-vinylpyrrolidone copolymer (i.e., Polyquaternium-44), and copolymers of vinylpyrrolidone and diallyldimethylammonium. Additionally, suitable cationic polymers include cationic polymers for personal care such as Luviquat® Supreme, Luviquat® Hold, Luviquat® UltraCare, Luviquat® FC 370, Luviquat® FC 550, Luviquat® FC 552, Luviquat® Excellence, GOHSEFIMER K210™, GOHSENX K-434, and combinations thereof.

Cationic polymers may also include an amino acid monomer (such compounds may also be referred to as polyamino acid compounds). Suitable polyamino acid compounds may include substantially any suitable amino acid monomer groups, for example, including polyarginine, polyhistidine, polyalanine, polyglycine, polytyrosine, polyproline, and polylysine. In example embodiments, polylysine may be a preferred polyamino acid. It will be understood that polylysine may include ε-polylysine and/or α-polylysine composed of D-lysine and/or L-lysine. The polylysine may thus include α-poly-L-lysine, α-poly-D-lysine, ε-poly-L-lysine, ε-poly-D-lysine, and mixtures thereof. The most preferred polylysine is ε-poly-L-lysine. It will further be understood that the polyamino acid compound (or compounds) may be used in any accessible form, e.g., the conjugate acid or base and salt forms of the polyamino acid may be used instead of (or in addition to) the polyamino acid.

Example cationic surfactants may include a nitrogen containing cationic surfactant, such as a quaternary amine compound or a polyquaternary amine compound. By polyquaternary amine it is meant that the compound includes from 2 to 4 quaternary ammonium groups such that the polyquaternary amine is a diquaternary amine compound, a triquaternary amine compound, or a tetraquaternary amine compound. Diquaternary amine compounds may include, for example, N,N′-alkylenebis(dialkylteradecylammonium bromide), N,N,N′,N′,N′-pentaalkyl-N-tallow-1,3-propane-diammonium dichloride, N,N′-hexamethylenebis(trialkylammonium hydroxide), decamethonium bromide, didodecyl-tetraalkyl-1,4-butanediaminium diiodide, 1,5-dialkyl-1,5-diazoniabicyclo(3.2.2) nonane dibromide, dialkylcocoamine bis(chloroalkyl) ether diquaternary ammonium salt, and the like. Triquaternary amine compounds may include, for example, N(1),N(6)-didoecyl-N(1),N(1),N(6),N(6)-tetraalkyl-1,6-hexanediaminium diiodide. Tetraquaternary amine compounds may include, for example, methanetetrayltetrakis(tetraalkylammonium bromide). The polyquaternary amine compound may further include a long chain alkyl group (e.g., having 10 or more carbon atoms), For example, a polyquaternary amine compound having a long chain alkyl group may include N,N′-methylenebis(dialkyltetradecylammonium bromide), N,N,N′,N′,N′-pentaalkyl-N-tallow-1,3-propane-diammonium dichloride, didodecyl-tetraalkyl-1,4-butanediaminium di iodide, and N(1),N(6)-didodecyl-N(1),N(1),N(6),N(6)-tetraalkyl-1,6-hexanediaminium diiodide.

Suitable anionic polymers may be homopolymers or copolymers and may include monomer units selected, for example, from carboxylic acid groups, sulfonic acid groups, and phosphonic acid groups. For example suitable anionic polymers may include poly(acrylic acid) (PAA), poly(methacrylic acid) (PMAA), poly(maleic acid) (PMA), poly(vinyl sulfonic acid) (PVSA), poly(styrene sulfonic acid), poly(2-acrylamido-2-methylpropane sulfonic acid), poly(styrenesulfonic acid-co-maleic acid), and combinations thereof. Preferred anionic polymers include poly(vinyl sulfonic acid) (PVSA), poly(styrene sulfonic acid) (PSSA), and mixtures thereof.

Example anionic surfactants may include a long carbon chain alky sulfonate, for example, including 10 or more carbon atoms. Suitable anionic surfactants include anionic surfactants having a functional group that carries a negative charge in a desired pH working space (e.g. sulfonate and sulfate), and an alkyl group. Preferred anionic surfactants may have the negatively charged functional group accompanied by ether and/or phenol. The negatively charged functional group is preferably a sulfate group or a sulfonate group. Example suitable anionic surfactants include disodium hexadecyldiphenyloxide disulfonate, ammonium polyoxyethylene styrenated aryl sulfate, and ammonium alkyl polyoxethylene ether sulfate (such as ammonium polyoxyethylene oleyl cetyl ether sulfate, and ammonium lauryl polyoxyethylene ether sulfate).

While example embodiments of the disclosed polishing composition may be supplied as a one-package system, the polishing composition may be also be provided as a two-package system. For example, the disclosed polishing composition may be supplied as a first package including the ceria particles and a second package including the oxidizer and the rate enhancing ligand. The first and second packages may be combined, e.g., by the end-user, on the polishing pad (e.g., via in-line mixing) or shortly before use (e.g., 1 week or less prior to use, 1 day or less prior to use, 1 hour or less prior to use, 10 minutes or less prior to use, or 1 minute or less prior to use).

The polishing composition of the invention may also be provided as a concentrate (or concentrates when two packages are employed) which is/are intended to be diluted with an appropriate amount of water prior to use. In such concentrated embodiments, the polishing composition concentrate may include the ceria particles, water, and other components such as the oxidizer, the rate enhancing ligand, and a biocide in amounts such that upon dilution of the concentrate with an appropriate amount of water each component of the polishing composition will be present in the polishing composition in an amount within the appropriate ranges recited above for each component. For example, the components may each be present in the polishing composition in an amount that is about 2 times (e.g., about 3 times, about 4 times, about 5 times, or even about 10 times) greater than the point of use concentrations recited above for each component so that, when the concentrate is diluted with an equal volume of (e.g., 2 equal volumes of water, 3 equal volumes of water, 4 equal volumes of water, or even 9 equal volumes of water respectively) each component will be present in the polishing composition in an amount within the ranges set forth above for each component. Furthermore, as will be understood by those of ordinary skill in the art, the concentrate may contain an appropriate fraction of the water present in the final polishing composition in order to ensure that other components are at least partially or fully dissolved in the concentrate.

The disclosed polishing compositions may be used to polish substantially any substrate, for example, including a carbon containing layer or film, but tend to be advantageous for polishing a substrate including a hard carbon layer or film. By hard carbon, it may be meant that the layer includes primarily carbon and has an elastic modulus of greater than about 6.5 GPa (e.g., greater than about 6.6 GPa, greater than about 6.7 GPa, greater than about 6.8 GPa, greater than about 6.9 GPa, or greater than about 7 GPa). Alternatively, by hard carbon, it may be meant that the layer includes primarily carbon and has a stiffness of greater than about 150 N/m (e.g., greater than about 160 N/m, greater than about 170 N/m, greater than about 180 N/m, greater than about 190 N/m, greater than about 200 N/m, greater than about 210 N/m, greater than about 220 N/m, greater than about 230 N/m, or greater than about 240 N/m).

The disclosed embodiments may be particularly advantageous when the hard carbon layer includes primarily carbon and has an elastic modulus of greater than about 6.5 GPa (e.g., greater than about 6.6 GPa, greater than about 6.7 GPa, greater than about 6.8 GPa, greater than about 6.9 GPa, or greater than about 7 GPa) and a stiffness of greater than about 150 N/m (e.g., greater than about 160 N/m, greater than about 170 N/m, greater than about 180 N/m, greater than about 190 N/m, greater than about 200 N/m, greater than about 210 N/m, greater than about 220 N/m, greater than about 230 N/m, or greater than about 240 N/m). The disclosed embodiments may be most advantageous when the hard carbon layer includes primarily carbon and has an elastic modulus of greater than about 7 GPa and a stiffness of greater than about 200 N/m (e.g., greater than about 210 N/m, greater than about 220 N/m, greater than about 230 N/m, or greater than about 240 N/m).

The disclosed embodiments may further advantageously provide high polishing selectivity (i.e., a high removal rate ratio) of hard carbon to dielectric layers such as silicon oxide (e.g., TEOS) and/or silicon nitride. In example embodiments the selectivity of hard carbon to silicon oxide or silicon nitride may be greater than about 10 (e.g., greater than about 20, greater than about 30, greater than about 40, or greater than about 50).

One aspect of the disclosed embodiments was the realization that achieving suitably high removal rate of hard carbon films may require the use of more chemically aggressive compositions, for example, including a ferric or ceric ion containing oxidizer in combination with a ceria abrasive. It was further discovered that such compositions may provide high removal rate selectivity to silicon oxide or silicon nitride films.

The polishing method of the invention is particularly suited for use in conjunction with a chemical mechanical polishing (CMP) apparatus. Typically, the apparatus includes a platen, which, when in use, is in motion and has a velocity that results from orbital, linear, or circular motion, a polishing pad in contact with the platen and moving with the platen when in motion, and a carrier that holds a substrate to be polished by contacting and moving relative to the surface of the polishing pad. The polishing of the substrate takes place by the substrate being placed in contact with the polishing pad and the polishing composition of the invention and then the polishing pad moving relative to the substrate, so as to abrade at least a portion of the substrate (particularly the hard carbon material described herein) to polish the substrate.

A substrate may be planarized or polished with the chemical mechanical polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, co-formed products thereof, and mixtures thereof.

The following examples further illustrate the invention but, of course, should not be construed as in any way limiting its scope.

### Example 1

An atomic force microscope (AFM) was used to measure the elastic modulus and stiffness of Spin on Carbon (SoC) film and a Tier 1 Hard Carbon film. The tests made use of a Bruker Dimension Icon AFM with a DDESP-2 probe. A 1 um by 1 um scan area was evaluated using force volume mode. The data was fit with a cone-sphere model and the elastic modulus and stiffness of each of the films was computed. The data is set forth in Table 1.

TABLE 1

| Carbon | Elastic | Stiffness |
|---|---|---|
| Film Type | Modulus (GPa) | (N/m) |
| Spin on Carbon | 6.2 | 120 |
| Tier 1 Hard Carbon | 7.4 | 245 |

As is evident from the data set forth in Table 1, the elastic modulus of the Tier 1 Hard Carbon is about 20% higher than the elastic modulus of the SoC and the stiffness of the Tier 1 Hard Carbon is about twice the stiffness of the SoC.

### Example 2

Eight polishing compositions were evaluated. Each of the compositions included a ceria abrasive and 10 mM picolinic acid. The pH of each composition was adjusted to 2.6. Compositions 2A-2G further included ferric nitrate nonahydrate. The detailed compositions are given in Table 2A (the ceria particle size was measured using a Malvern® Zetasizer®).

TABLE 2A

| | | Ceria | Ferric | Picolinic |
|---|---|---|---|---|
| Polishing | Ceria | Particle | Nitrate | Acid |
| Composition | (wt. %) | Size (nm) | Nonahydrate (mM) | (mM) |
| 2A | 0.15 | 145 | 5.4 | 10 |
| 2B | 0.3 | 145 | 5.4 | 10 |
| 2C | 0.6 | 145 | 5.4 | 10 |
| 2D | 0.15 | 145 | 10.8 | 10 |
| 2E | 0.15 | 180 | 5.4 | 10 |
| 2F | 0.15 | 141 | 5.4 | 10 |
| 2G | 0.15 | 81 | 5.4 | 10 |
| 2H | 0.07 | 180 | 0 | 10 |

The CMP performance of polishing compositions 2A-2H was evaluated using a Logitech 2 benchtop polishing machine with an E6088 polishing pad (Entegris) and in-situ conditioning using a Saesol DS8051 conditioner. Blanket Tier 1 Hard Carbon, TEOS and LP-SiN removal rates were obtained by polishing corresponding wafers at a downforce of 3.0 psi (20.6 kPa), a platen speed of 93 rpm, a head speed of 87 rpm, and a slurry flow rate of 50 mL/min for 60 seconds. The results are set forth in Table 2B.

TABLE 2B

| Polishing | Tier 1 HC | TEOS RR | LP SiN RR | HC:TEOS |
|---|---|---|---|---|
| Composition | RR (Å/min) | (Å/min) | (Å/min) | Selectivity |
| 2A | 553 | 26 | 8 | 21 |
| 2B | 902 | 36 | 24 | 25 |
| 2C | 762 | 60 | 13 | 13 |
| 2D | 1327 | 32 | 20 | 41 |
| 2E | 1174 | 78 | 13 | 15 |
| 2F | 445 | 24 | 11 | 18 |
| 2G | 349 | 5 | 8 | 70 |
| 2H | 419 | 3967 | 24 | 0.01 |

As is evident from the data set forth in Table 2B, the disclosed polishing compositions including a ferric nitrate oxidizer, a picolinic acid rate enhancing ligand, and various ceria particles achieved high polishing rates of the Tier 1 hard carbon and corresponding high selectivities to TEOS and SiN. It was further observed that the compositions (e.g., 2E) having larger ceria particles achieved higher removal rates on both the hard carbon and TEOS films.

### Example 3

Five polishing compositions were evaluated. Each of the compositions included 0.15 weight percent of the same ceria abrasive used in polishing composition 2A, 5.4 mM ferric nitrate nonahydrate, and 10 mM picolinic acid. The pH values of the final polishing compositions were stepped from 2.1 to 4.1 as indicated in Table 3.

The CMP performance of polishing compositions 3A-3E was evaluated using a Logitech 2 benchtop polishing machine with an E6088 polishing pad (Entegris) and in-situ conditioning using a Saesol DS8051 conditioner. Blanket Tier 1 Hard Carbon, TEOS and LP-SiN removal rates were obtained by polishing corresponding wafers at a downforce of 3.0 psi (20.6 kPa), a platen speed of 93 rpm, a head speed of 87 rpm, and a slurry flow rate of 50 mL/min for 60 seconds. The results are set forth in Table 3.

TABLE 3

| Polishing | | Tier 1 HC | TEOS RR | LP SiN RR | HC:TEOS |
|---|---|---|---|---|---|
| Composition | pH | RR (Å/min) | (Å/min) | (Å/min) | Selectivity |
| 3A | 2.1 | 336 | 45 | 8 | 7 |
| 3B | 2.6 | 997 | 24 | 17 | 42 |
| 3C | 3.1 | 1548 | 40 | 32 | 39 |
| 3D | 3.6 | 1601 | 62 | 45 | 26 |
| 3E | 4.1 | 1433 | 74 | 23 | 19 |

As is readily apparent from the results set forth in Table 3, the polishing rate of the hard carbon reached a maximum at a pH value in a range from about three to about four (e.g., at about 3.1 or 3.6 in compositions 3C and 3D) and the removal rate selectivities reached a maximum at a pH value in a range from about 2.5 to about 3 (e.g., at about 2.6 and 3.1 in compositions 3B and 3C).

### Example 4

Five polishing compositions were evaluated. Each of the compositions included 0.15 weight percent of the same ceria abrasive used in polishing composition 2E, 5.4 mM of an oxidant/Lewis acid (listed in Table 4), and 10 mM picolinic acid. The pH of each composition was 2.6.

The CMP performance of polishing compositions 4A-4E was evaluated using a Logitech 2 benchtop polishing machine with an E6088 polishing pad (Entegris) and in-situ conditioning using a 3M A122 conditioner. Blanket Tier 1 Hard Carbon, TEOS and LP-SiN removal rates were obtained by polishing corresponding wafers at a downforce of 3.0 psi (20.6 kPa), a platen speed of 93 rpm, a head speed of 87 rpm, and a slurry flow rate of 50 mL/min for 60 seconds. The results are set forth in Table 4.

TABLE 4

| | Oxidant/ | Tier 1 | | LP SiN | |
|---|---|---|---|---|---|
| Polishing | Lewis | HC RR | TEOS RR | RR | HC:TEOS |
| Composition | Acid | (Å/min) | (Å/min) | (Å/min) | Selectivity |
| 4A | Fe(NO₃)₃•9H₂O | 1423 | 16 | 13 | 89 |
| 4B | Al(NO₃)₃ | 54 | 671 | 14 | 0.1 |
| 4C | Ce(III)(NH₄)₂(NO₃)₅ | 164 | 406 | 24 | 0.4 |
| 4D | Mn(NO₃)₂ | 61 | 381 | 26 | 0.2 |
| 4E | ZrO(NO₃)₂ | 292 | 46 | 18 | 6 |

As is readily apparent from the results set forth in Table 4, composition 4A including the ferric ion containing oxidizer achieved the highest hard carbon removal rate and removal rate selectivities. Compositions 4B-4E including other Lewis acids (e.g., Zr, Ce(III), Mn, and Al) provided minimal increase to the hard carbon removal rate.

### Example 5

Four polishing compositions were evaluated. Each of the compositions included 0.15 weight percent of the same ceria abrasive used in polishing composition 2E, 5.4 mM of ferric nitrate nonahydrate, and 10 mM of a ligand (listed in Table 5). The pH of each composition was 2.6.

The CMP performance of polishing compositions 5A-5D was evaluated using a Logitech 2 benchtop polishing machine with an E6088 polishing pad (Entegris) and in-situ conditioning using a 3M A122 conditioner. Blanket Tier 1 Hard Carbon, TEOS and LP-SiN removal rates were obtained by polishing corresponding wafers at a downforce of 3.0 psi (20.6 kPa), a platen speed of 93 rpm, a head speed of 87 rpm, and a slurry flow rate of 50 mL/min for 60 seconds. The results are set forth in Table 5.

TABLE 5

| | | Tier 1 | TEOS | LP SiN | |
|---|---|---|---|---|---|
| Polishing | | HC RR | RR | RR | HC:TEOS |
| Composition | Ligand | (Å/min) | (Å/min) | (Å/min) | Selectivity |
| 5A | Picolinic Acid | 1423 | 16 | 13 | 89 |
| 5B | Lactic Acid | 64 | 45 | 18 | 1 |
| 5C | Dipicolinic Acid* | 409 | 68 | 139 | 6 |
| 5D | Glycine | 37 | 35 | 20 | 1 |

*Caused growth in ceria particle size

As is readily apparent from the results set forth in Table 5, composition 5A including the picolinic acid achieved the highest hard carbon removal rate and removal rate selectivities. Composition 5C, including dipicolinic acid, provided a moderate removal rate increase but was also observed to increase the particle size of the ceria.

### Example 6

Eight polishing compositions were evaluated. Each of the compositions included 0.15 weight percent of the same ceria abrasive used in polishing composition 2E, 5.4 mM of ferric nitrate nonahydrate, and 10 mM of a ligand (listed in Table 5). The pH of each composition was 3.1.

The CMP performance of polishing compositions 6A-6J was evaluated using a Logitech 2 benchtop polishing machine with an E6088 polishing pad (Entegris) and in-situ conditioning using a 3M A122 conditioner. Blanket Tier 1 Hard Carbon, TEOS and LP-SiN removal rates were obtained by polishing corresponding wafers at a downforce of 3.0 psi (20.6 kPa), a platen speed of 93 rpm, a head speed of 87 rpm, and a slurry flow rate of 50 mL/min for 60 seconds. The results are set forth in Table 6.

TABLE 6

| | | Tier 1 | TEOS | |
|---|---|---|---|---|
| Polishing | | HC RR | RR | HC:TEOS |
| Composition | Ligand | (Å/min) | (Å/min) | Selectivity |
| 6A | Picolinic Acid | 2086 | 71 | 29 |
| 6B | Pyrrole-2- | 3130 | 108 | 29 |
| | Carboxylic Acid | | | |
| 6C | 5-Hydroxypicolinic | 63 | 88 | 1 |
| | Acid * | | | |
| 6D | 6-Hydroxypicolinic | 1296 | 1161 | 1 |
| | Acid * | | | |
| 6E | 3-Aminobenzoic Acid | 76 | 91 | 1 |
| 6F | 4-Aminobenzoic Acid | 1202 | 51 | 24 |
| 6G | Benzohydroxamic Acid | 984 | 132 | 7 |
| 6H | Salicylic | 193 | 98 | 2 |
| | Hydroxamic Acid * | | | |
| 6I | Nicotinic Acid | 75 | 67 | 1 |
| 6J | Iso- | 69 | 42 | 1 |
| | nicotinic Acid * | | | |

* Caused growth in ceria particle size

As is readily apparent from the results set forth in Table 6, compositions 6A, 6B, 6D, 6F, and 6G including, picolinic acid, pyrrole-2-carboxylic acid, 6-hydroxypicolinic acid, 4-aminobenzoic acid, or benzohydroxamic acid, achieved the highest hard carbon removal rate and removal rate (with compositions 6B achieving a particularly high hard carbon removal rate). Compositions 6A, 6B, and 6F were particularly advantageous in that they also achieved a high removal rate selectivity to TEOS and exhibited a stable ceria particle size.

### Example 7

Four polishing compositions were evaluated. Each of the compositions included 0.15 weight percent of the same ceria abrasive used in polishing composition 2A, 5.4 mM of an oxidizer (listed in Table 6), and 10 mM of picolinic acid. The pH of each composition was 2.6.

The CMP performance of polishing compositions 7A-7D was evaluated using a Logitech 2 benchtop polishing machine with an E6088 polishing pad (Entegris) and in-situ conditioning using a Saesol DS8051 conditioner. Blanket Tier 1 Hard Carbon, TEOS and LP-SiN removal rates were obtained by polishing corresponding wafers at a downforce of 3.0 psi (20.6 kPa), a platen speed of 93 rpm, a head speed of 87 rpm, and a slurry flow rate of 50 mL/min for 60 seconds. The results are set forth in Table 7.

TABLE 7

| | | Tier 1 HC | TEOS | LP SiN | |
|---|---|---|---|---|---|
| Polishing | | RR | RR | RR | HC:TEOS |
| Composition | Oxidizer | (Å/min) | (Å/min) | (Å/min) | Selectivity |
| 7A | Fe(NO₃)₃•9H₂O | 997 | 24 | 17 | 42 |
| 7B | (NH4)₂[Ce(IV)(NO₃)₆] | 789 | 206 | 32 | 4 |
| 7C | (NH₄)₂S₂O₈ | 89 | 300 | 49 | 0.3 |
| 7D | (NH₄)IO₄ | 4 | 59 | 591 | 0.1 |

As is readily apparent from the data set forth in Table 6, the compositions (7A and 7B) including the Fe(III) and Ce(IV) containing oxidizers achieved the highest hard carbon removal rate. The Fe(III) containing oxidizer provided superior selectivity, particularly to TEOS.

### Example 8

Four polishing compositions were evaluated. Each of the compositions included 0.15 weight percent of the same ceria abrasive used in polishing composition 2E, 5.4 mM of ferric nitrate nonahydrate, and 10 mM of picolinic acid at a pH of 3.1. Compositions 8B, 8C, and 8D further included potassium nitrate to increase the conductivity of the composition to about 3000 μS, 4000 μS, and 5000 μS, respectively.

The CMP performance of polishing compositions 8A-8D was evaluated using a Logitech 2 benchtop polishing machine with an E6088 polishing pad (Entegris) and in-situ conditioning using a Saesol DS8051 conditioner. Blanket Tier 1 Hard Carbon, TEOS and LP-SiN removal rates were obtained by polishing corresponding wafers at a downforce of 3.0 psi (20.6 kPa), a platen speed of 93 rpm, a head speed of 87 rpm, and a slurry flow rate of 50 mL/min for 60 seconds. The results are set forth in Table 8.

TABLE 8

| Polishing | Conductivity | Tier 1 HC | TEOS RR | HC:TEOS |
|---|---|---|---|---|
| Composition | (μS/cm) | RR (Å/min) | (Å/min) | Selectivity |
| 8A | 1776 | 2086 | 71 | 29 |
| 8B | 2974 | 2304 | 107 | 22 |
| 8C | 4041 | 2380 | 72 | 33 |
| 8D | 5065 | 2099 | 87 | 24 |

As is readily apparent from the data set forth in Table 8, compositions (8B and 8C) having increased conductivity (e.g., in a range from about 2500 μS to about 5000 μS or from about 3000 μS to about 4000 μS) achieved the highest hard carbon removal rates. Composition 7C, having a conductivity of about 4000 μS, achieved the highest selectivity to TEOS.

### Example 9

Two polishing compositions were evaluated. The first composition (9A) was identical to compositions 4A and 5A. The second composition (9B) included 0.6 wt. % of Stober silica having a DLS particles size of 185 nm, 5.4 mM ferric nitrate nonahydrate, 4800 ppm by weight malonic acid, and 400 ppm by weight polyDADMAC, at a pH of 2.15.

The CMP performance of polishing compositions 9A and 9B was evaluated using a Logitech 2 benchtop polishing machine with an E6088 polishing pad (Entegris) and in-situ conditioning using a Saesol DS8051 conditioner. Blanket Tier 1 Hard Carbon, Spin on Carbon, and TEOS removal rates were obtained by polishing corresponding wafers at one of two polishing conditions. The first polishing conditions were as described above and included a downforce of 3.0 psi (20.6 kPa), a platen speed of 93 rpm, a head speed of 87 rpm, and a slurry flow rate of 50 mL/min for 60 seconds. The second polishing conditions included a downforce of 2.0 psi (13.7 kPa), a platen speed of 63 rpm, a head speed of 57 rpm, and a slurry flow rate of 50 mL/min for 60 seconds. The second polishing conditions were used to polish TEOS and Spin on Carbon wafers with the second polishing composition. The first polishing conditions were used were used for all other wafers. The results are set forth in Table 9.

TABLE 9

| Polishing | Tier 1 HC | SOC RR | TEOS RR | HC:TEOS |
|---|---|---|---|---|
| Composition | RR (Å/min) | (Å/min) | (Å/min) | Selectivity |
| 9A | 1748 * | 2322 * | 13 * | 134 |
| 9B | 11 * | 6384 ** | 9 ** | 1 |

* First polishing conditions (3 psi, 93/87 PS/HS)
** Second polishing conditions (2 psi, 63/57 PS/HS)

As is apparent in the results set forth in Table 9, inventive composition 9A achieved high removal rates on both the hard carbon and spin on carbon films as well as a high hard carbon to TEOS removal rate selectivity. In contrast composition 9B achieved a very high removal rate on the spin on carbon film but a very low (virtually zero) removal rate on the hard carbon film.

### Example 10

Ten polishing compositions were evaluated. Each of the compositions included the same ceria abrasive used in polishing composition 2E, a ferric nitrate nonahydrate (FEN) or cerium ammonium nitrate (CAN) oxidizer, and 10 mM picolinic acid at a pH of 2.6. The detailed compositions are given in Table 10A.

TABLE 10A

| Polishing | Ceria | Oxidizer | |
|---|---|---|---|
| Composition | (wt. %) | (wt. %) | |
| 10A | 0.15 | 0.22 | FEN |
| 10B | 0.15 | 0.44 | FEN |
| 10C | 0.225 | 0.33 | FEN |
| 10D | 0.3 | 0.22 | FEN |
| 10E | 0.3 | 0.44 | FEN |
| 10F | 0.15 | 0.15 | CAN |
| 10G | 0.15 | 0.3 | CAN |
| 10H | 0.225 | 0.225 | CAN |
| 10I | 0.3 | 0.15 | CAN |
| 10J | 0.3 | 0.3 | CAN |

The CMP performance of polishing compositions 10A-10J was evaluated using a Reflexion® (Applied Materials) polishing machine with an E6088 polishing pad (Entegris) and in-situ conditioning using a 3M-A122L conditioner. 300 mm blanket Tier 1 Hard Carbon and LP-SiN removal rates were obtained by polishing corresponding wafers at a downforce of 3.0 psi (20.6 kPa), a platen speed of 93 rpm, a head speed of 87 rpm, and a slurry flow rate of 250 mL/min for 60 seconds. The results are set forth in Table 10B.

TABLE 2B

| Polishing | Tier 1 HC | LP SiN RR | HC:SiN |
|---|---|---|---|
| Composition | RR (Å/min) | (Å/min) | Selectivity |
| 10A | 680 | 15 | 45 |
| 10B | 681 | 15 | 45 |
| 10C | 705 | 19 | 37 |
| 10D | 702 | 19 | 37 |
| 10E | 722 | 22 | 33 |
| 10F | 164 | 30 | 5 |
| 10G | 274 | 140 | 2 |
| 10H | 328 | 103 | 3 |
| 10I | 772 | 154 | 5 |
| 10J | 757 | 178 | 4 |

As is evident from the data set forth in Table 10B, polishing compositions 10A-10E achieved high removal rates of hard carbon and a high selectivity to SiN across the range of ceria and ferric nitrate nonahydrate concentrations tested. Polishing compositions 10I and 10J achieved high removal rates of hard carbon. Within the ranges tested, the ferric oxidizer provided a more stable high hard carbon removal rate while the ceric oxidizer provided a more tunable hard carbon removal rate.

It will be understood that the recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
a liquid carrier;
ceria particles in the liquid carrier;
an oxidizer including an iron (iii) compound or a cerium (IV) compound;
an acid having a ligand including an aromatic group or a nitrogen containing aromatic group; and
a pH of less than about 4.

2. The chemical-mechanical polishing composition of claim 1, wherein the acid includes pyrrole carboxylic acid, 6-hydroxypicolinic acid, benzohydroxamic acid, or a mixture thereof; and
a pH of less than about 4.

3. The composition of claim 1, comprising from about 0.05 weight percent to about 0.5 weight percent of the ceria particles at point of use.

4. The composition of claim 1, wherein the ceria particles have a particle size in a range from about 50 nm to about 250 nm.

5. The composition of claim 1, wherein the oxidizer comprises cerium (IV) ammonium nitrate.

6. The composition of claim 1, wherein the oxidizer comprises an iron (III) nitrate compound.

7. The composition of claim 1, wherein the acid comprises picolinic acid, pyrrole carboxylic acid, a 6-hydroxypicolinic acid, 4-aminobenzoic acid, benzohydroxamic acid or a mixture thereof.

8. The composition of claim 1, wherein the acid comprises pyrrole carboxylic acid.

9. The composition of claim 1, comprising from about 3 mM to about 20 mM of the oxidizer at point of use.

10. The composition of claim 1, comprising from about 5 mM to about 20 mM of the acid at point of use.

11. The composition of claim 1, wherein the pH is in a range from about 2.5 to about 3.5.

12. The composition of claim 1, having an electrical conductivity in a range from about 2000 wherein the pH is in a range from about 2200 μS/cm to about 5000 μS/cm.

13. The composition of claim 1, wherein
the oxidizer comprises cerium (IV) ammonium nitrate; and
the acid comprises picolinic acid, pyrrole carboxylic acid, 4-aminobenzoic acid, or a mixture thereof.

14. The composition of claim 1, wherein
the oxidizer comprises a ferric nitrate compound; and
the acid comprises pyrrole carboxylic acid.

15. The composition of claim 1, comprising:
from about 0.05 weight percent to about 0.5 weight percent of the ceria particles at point of use;
from about 3 mM to about 20 mM of the oxidizer at point of use; and
from about 5 mM to about 20 mM of the acid at point of use.

16. A method for chemical mechanical polishing a substrate, the method comprising:
(a) contacting the substrate with the polishing composition in claim 1;
(b) moving the polishing composition relative to the substrate; and
(c) abrading the substrate to remove a portion of at least one hard carbon layer from the substrate and thereby polish the substrate.

17. The method of claim 16, wherein the hard carbon layer has an elastic modulus of greater than about 7 GPa.

18. The method of claim 16, wherein the hard carbon layer has a stiffness of greater than about 150 N/m.

19. The method of claim 16, wherein the hard carbon layer has a stiffness of greater than about 200 N/m.

20. The method of claim 16, wherein the substrate further includes a silicon oxide layer or a silicon nitride layer and abrading the substrate removes at least a portion of the silicon oxide layer or the silicon nitride layer.
